(19) United States
(12) Patent Application Publication
(10) Pub. No.: US 2006/0035103 A1
(43) Pub. Date: Feb. 16, 2006

(54) Method for the inner coating of a component with a cavity and component with an inner coating

(76) Inventors: Rene Jabado, Berlin (DE); Ursus Kruger, Berlin (DE); Daniel Kortvelyessy, Berlin (DE); Volkmar Luthen, Berlin (DE); Ralph Reiche, Berlin (DE); Michael Rindler, Schoneiche (DE); Raymond Ullrich, Schonwalde (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/106,267

(22) Filed: Apr. 14, 2005

(30) Foreign Application Priority Data
Apr. 16, 2004 (EP) EP04009101

(51) Int. Cl. C23C 16/26; B21D 39/00

(52) U.S. Cl. 428/621; 427/249.1

(57) ABSTRACT

Inner coatings according to the prior art often do not produce a uniform coating. The method according to the invention for the coating of a component with a cavity is characterized in that a coating material is mixed with a carrier material and introduced into the cavity, the carrier material decomposing at the evaporating temperature of the coating material, or has already decomposed, and the coating material being deposited from the gas phase on the component.

### CROSS REFERENCE TO RELATED APPLICATION

This application claims priority of the European application No. 04009101 EP filed Apr. 16, 2004, which is incorporated by reference herein in its entirety.

### FIELD OF THE INVENTION

The invention relates to a method for the coating of an inner surface of a component with a cavity according to claim 1 and to a component with an inner coating according to claim 14.

### BACKGROUND OF THE INVENTION

Components which have a cavity are often coated on the inside. This generally takes place by a CVD process, in which metal-containing precursors, for example aluminum- or chromium-containing precursors, are introduced into the cavity, a chemical reaction induced by an increase in temperature causing a chemical reaction which produces a gas phase of the metals to take place. The gas phase is deposited on the inner surfaces of the cavity, so that a coating is created.

U.S. Pat. No. 5,254,413 discloses a method for the coating of a hole, in which a filling material of ceramic and aluminum is filled into the hole and heated, so that an aluminum coating is obtained. The ceramic constituents do not decompose and must be removed at the end of the process.

Such a method is similarly used for the inner coating of cooling configurations and/or through-openings, such as for example cooling air ducts of turbine components, in particular gas turbine components. Such cooling air ducts are coated with aluminum and/or chromium, which for example diffuses into the substrate, to provide protection against corrosion. This coating is oxidized on during operation. The oxide film created as a result prevents the substrate of the blade being subjected to further corrosive attack. In the case of an aluminum coating (inner alitizing), the aluminum is for the most part converted into aluminum oxide (Al₂O₃) and thereby stops the inner surfaces of the cooling air ducts from being subjected to further attack. Since the meandering cooling air ducts in the interior of a turbine blade in particular are sometimes of a considerable length, the uniform coating of the inner surfaces presents a problem. In particular, complete coverage of the entire inner surface and the achievement of a uniform layer thickness from the inlet to the outlet of the cooling air ducts can only be ensured with difficulty in the previous CVD processes. The cause of this is, for example, the considerable reduction of metal concentration in the gas phase over the length of the ducts to be coated.

### SUMMARY OF THE INVENTION

It is therefore the object of the invention to present an inner coating method and a component which overcome this problem.

The object is achieved by a method according to the claims and by a component according to the claims.

Further advantageous measures, which can be combined with one another in an advantageous way, are listed in the subclaims.

### BRIEF DESCRIPTION OF THE DRAWINGS

In the drawing:

FIGS. 1, 2 show components given by way of example, for which the method according to the invention can be applied,

FIG. 3 shows method steps according to the invention,

FIG. 4 shows a coating produced as a result by way of example,

FIG. 5 shows a turbine blade,

FIG. 6 shows a combustion chamber,

FIG. 7 shows a cooling configuration and

FIG. 8 shows a gas turbine.

### DETAILED DESCRIPTION OF THE INVENTION

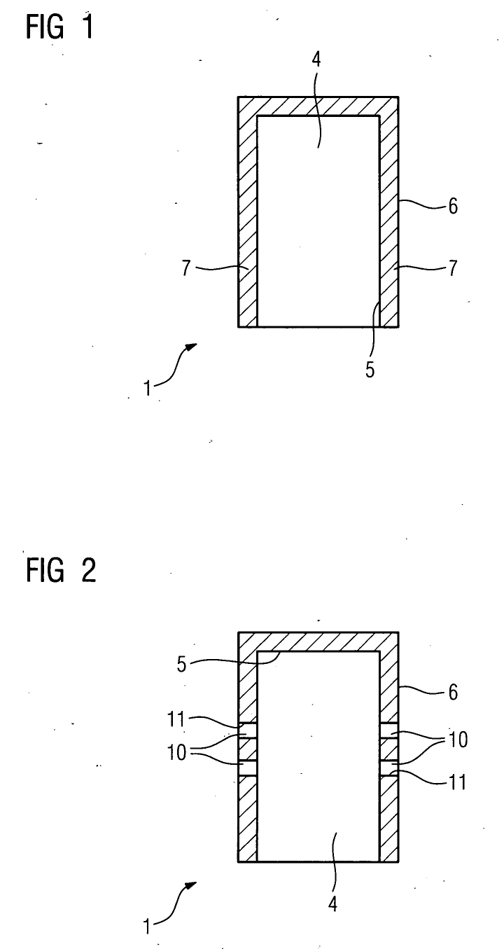

FIG. 1 shows a component 1, which has a cavity 4 and outer walls 7.

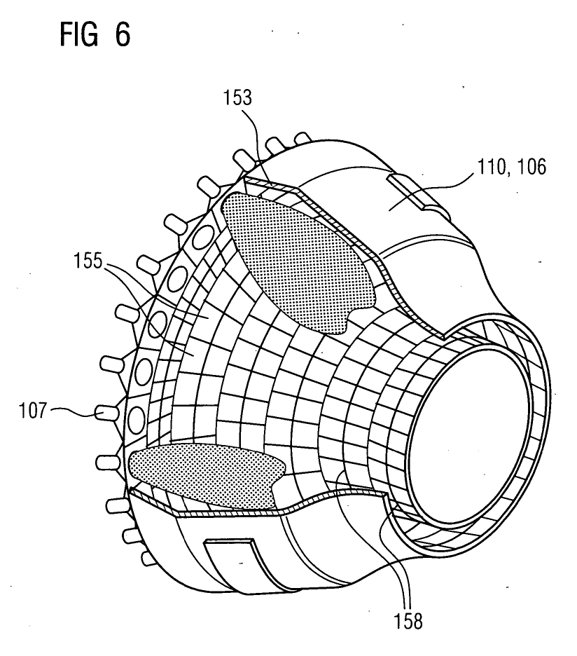

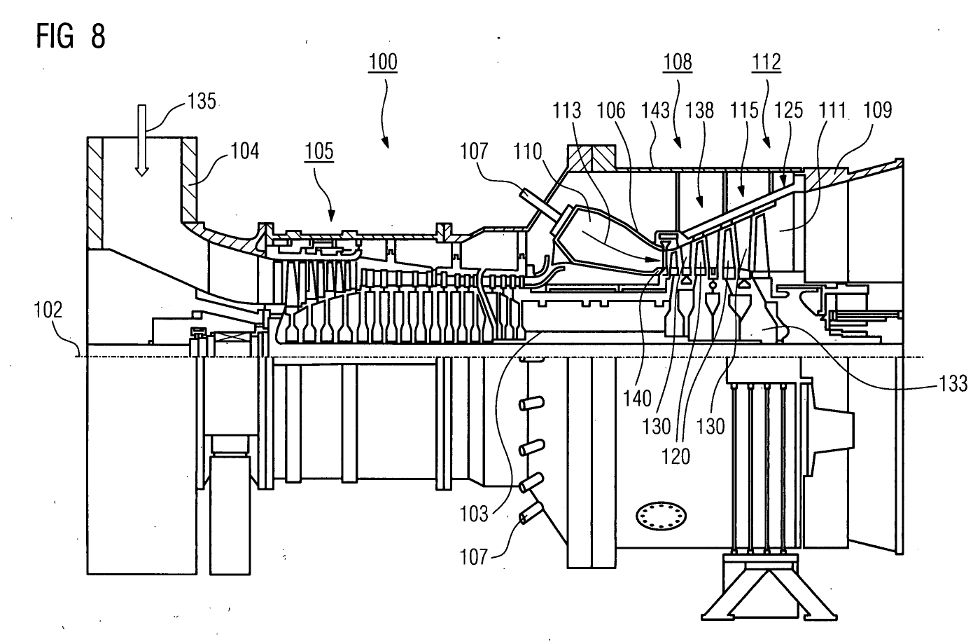

This is, for example, a turbine blade 120, 130 of a turbine 100 (FIG. 8) (steam or gas turbine) or combustion chamber elements 155 (FIG. 6) of a turbine 100.

The outer wall 7 has an inner surface 5, which is to be coated, and an outer surface 6.

FIG. 2 shows a further component 1, for which the method according to the invention can be applied.

On the basis of FIG. 1, the component 1 has cooling air ducts or through-holes 10, which are to be coated on the inner surface 11.

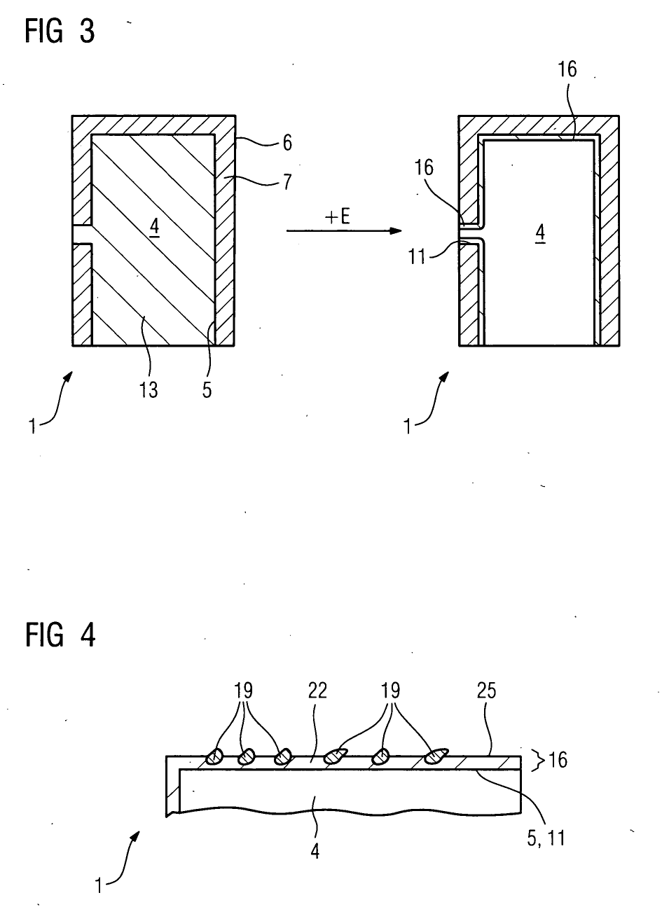

FIG. 3 shows a sequence of the method according to the invention, given by way of example.

A paste 13 is introduced, for example injected, into the cavity 4 or the inner cooling configuration and/or into the cooling air ducts 10.

The paste 13 comprises a carrier material and a coating material, which is present in the carrier material, for example in that the carrier material and the coating material are mixed with each other.

The coating material is, for example, uniformly distributed in the carrier material.

The coating material has a specific decomposing or evaporating temperature, at which the carrier material is no longer thermally stable, that is to say it decomposes or evaporates.

The carrier material is thermally stable at room temperature, i.e. it does not decompose.

In particular, the coating material is present in the carrier material in the form of microparticles and/or nanoparticles (<1 micrometer, in particular<500 or 100 nanometers) and may be metallic or ceramic.

It is advantageous to use nanoparticles to provide the matrix of the coating 16 to be produced, i.e. the coating material is formed for the most part (for example >=50%) or entirely by nanoparticles.

Similarly, the nanoparticles may be conducive to a compaction of the micrometer particles (>1 micrometer, in particular >10 micrometers) of the coating 16, if the coating material comprises for the most part (for example >=50%) particles of micrometer size.

Similarly, the coating material may have a number of metallic and/or ceramic elements or components, such as for example the alloying constituents of an MCrAlY coating.

The carrier material is, for example, a polymer, in particular a polyurethane.

Other carrier materials are conceivable and are selected according to the coating material and its physical properties (evaporating temperature).

The method can be advantageously applied for inner alitizing and/or inner chromizing.

Once the paste 13 has been introduced into the cavity 4 or into the cooling configuration and/or the cooling air duct 10, energy E, for example thermal energy, is supplied to the component 1 with the paste 13, it being possible for the heating to take place in a vacuum oven if oxidation of the component 1 is to be avoided.

On account of the heat supply, the carrier material decomposes and the coating material goes over into a gas phase and is deposited on the inner surfaces 5, 11, so that a coating 16 forms there.

The decomposing carrier material can be pumped away.

For better bonding, a heat treatment can be carried out with the coating 16, or the coating 16 is for the most part allowed to diffuse into the substrate or wall 7 of the component 1, 120, 130, 155.

If, in addition to the coating material, a coarse material 19 is added to the carrier material, a microstructure/macrostructure according to FIG. 4 is formed.

The coarse material 19 has a particle size in the micrometer range and is consequently considerably greater than the nanoparticles used by way of example for the coating material. The temperature for the gas phase formation of the coating material may be chosen such that the coarse material 19, which for example consists of the same material as the coating material, does not go over into the gas phase as quickly on account of its larger form of particle and is incorporated as a coarser particle in a matrix of the coating 16.

Similarly, the coating material may be metallic and the coarse material 19 is a material which is stable at the evaporating temperature of the metal, such as for example a ceramic (for example aluminum oxide), so that the coarse material 19 is incorporated into the coating 16, so that it forms a secondary phase there.

As a result, for example, the abrasive resistance of the coating 16 is increased.

However, the resultant coating 16 may also be rough, for example, and therefore contains particles 19 which protrude from a surface 25 of a matrix coating 22 structured to be finer than the coarse particles 19, and consequently produce turbulent flows when a medium flows past the surface, so that the flow resistance is reduced.

The method can also be used for outer coating, involving applying the mixture 13 of carrier material and coating material to an outer surface 6 and heating it. In this case, it may be necessary to ensure by a further top coating that the gaseous coating material forming is deposited on the surface 6 and does not escape.

In particular, the paste 13 has no activator (see discussion of the prior art of U.S. Pat. No. 5,254,413), as is used in the case of a coating method in which aluminum and a halogen are used as an activator, so that gaseous aluminum chloride is formed, leading to the deposition of aluminum on a surface.

Similarly, the paste 13 has no filler materials which have to be removed at the end of the method, i.e. the carrier material has decomposed and evaporated completely and the coating material has been deposited at least for the most part or entirely as a coating 16, 22.

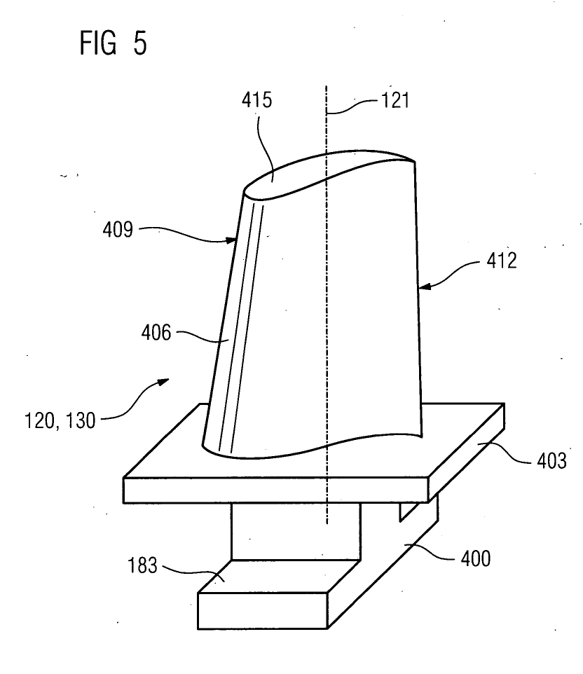

FIG. 5 shows in a perspective view a blade 120, 130, which extends along a longitudinal axis 121.

The blade 120 may be a moving blade 120 or stationary blade 130 of a turbomachine 100. The turbomachine may be a gas turbine of an aircraft or a power plant for generating electricity, a steam turbine or a compressor.

The blade 120, 130 has, following one after the other along the longitudinal axis 121, a fastening region 400, an adjoining blade platform 403 and a blade airfoil 406.

As a stationary blade 130, the blade may have a further platform at its blade tip 415 (not represented).

In the fastening region 400 there is formed a blade root 183, which serves for the fastening of the blades 120, 130 to a shaft or a disk (not represented).

The blade root 183 is designed for example as a hammer head. Other designs as a firtree or dovetail root are possible.

The blade 120, 130 has for a medium which flows past the blade airfoil 406 a leading edge 409 and a trailing edge 412.

In the case of conventional blades 120, 130, solid metallic materials are used for example in all the regions 400, 403, 406 of the blade 120, 130.

The blade 120, 130 may in this case be produced by a casting method, also by means of directional solidification, by a forging method, by a milling method or combinations of these.

Workpieces with a monocrystalline structure or structures are used as components for machines which are exposed to high mechanical, thermal and/or chemical loads during operation.

The production of monocrystalline workpieces of this type takes place for example by directional solidification from the melt. This involves casting methods in which the liquid metallic alloy solidifies to form the monocrystalline structure, i.e. to form the monocrystalline workpiece, or in a directional manner. Dendritic crystals are thereby oriented along the thermal flow and form either a columnar grain structure (i.e. grains which extend over the entire length of the workpiece and are commonly referred to here as directionally solidified) or a monocrystalline structure, i.e. the entire workpiece comprises a single crystal. In these methods, the transition to globulitic (polycrystalline) solidification must be avoided, since undirected growth necessarily causes the formation of transversal and longitudinal grain boundaries, which nullify the good properties of the directionally solidified or monocrystalline component.

While reference is being made generally to solidified structures, this is intended to mean both monocrystals, which have no grain boundaries or at most small-angle grain boundaries, and columnar crystal structures, which indeed have grain boundaries extending in the longitudinal direction but no transversal grain boundaries. These second-mentioned crystalline structures are also referred to as directionally solidified structures.

Such methods are known from U.S. Pat. No. 6,024,792 and EP 0 892 090 A1.

Refurbishment means that components 120, 130 may have to be freed of protective layers after use (for example by sandblasting). This is followed by removal of the corrosion and/or oxidation layers or products. If applicable, cracks in the component 120, 130 are then also repaired. This is followed by recoating of the component 120, 130 and renewed use of the component 120, 130.

The blade 120, 130 may be hollow and coated on the inside according to the method described above or be of a solid form.

If the blade 120, 130 is to be cooled, it is hollow and may also have film cooling holes (not represented). As protection against corrosion, the blade 120, 130 has, for example, corresponding, usually metallic, coatings and, as protection against heat, usually also a ceramic coating.

FIG. 6 shows a combustion chamber 110 of a gas turbine. The combustion chamber 110 is designed for example as what is known as an annular combustion chamber, in which a multiplicity of burners 102, arranged around the turbine shaft 103 in the circumferential direction, open out into a common combustion chamber space. For this purpose, the combustion chamber 110 is designed as a whole as an annular structure, which is resistant around the turbine shaft 103.

To achieve a comparatively high efficiency, the combustion chamber 110 is designed for a comparatively high temperature of the working medium M of approximately 1000° C. to 1600° C. To permit a comparatively long operating time even with these operating parameters that are unfavorable for the materials, the combustion chamber wall 153 is provided on its side facing the working medium M with an inner lining formed by heat shielding elements 155. Each heat shielding element 155 is provided on the working medium side with a particularly heat-resistant protective layer or is produced from material that is resistant to high temperature. On account of the high temperatures in the interior of the combustion chamber 110, a cooling system is also provided for the heat shielding elements 155 or for their holding elements.

The materials of the combustion chamber wall and its coatings may be similar to the turbine blades.

The combustion chamber 110 is designed in particular for detecting losses of the heat shielding elements 155. For this purpose, a number of temperature sensors 158 are positioned between the combustion chamber wall 153 and the heat shielding elements 155.

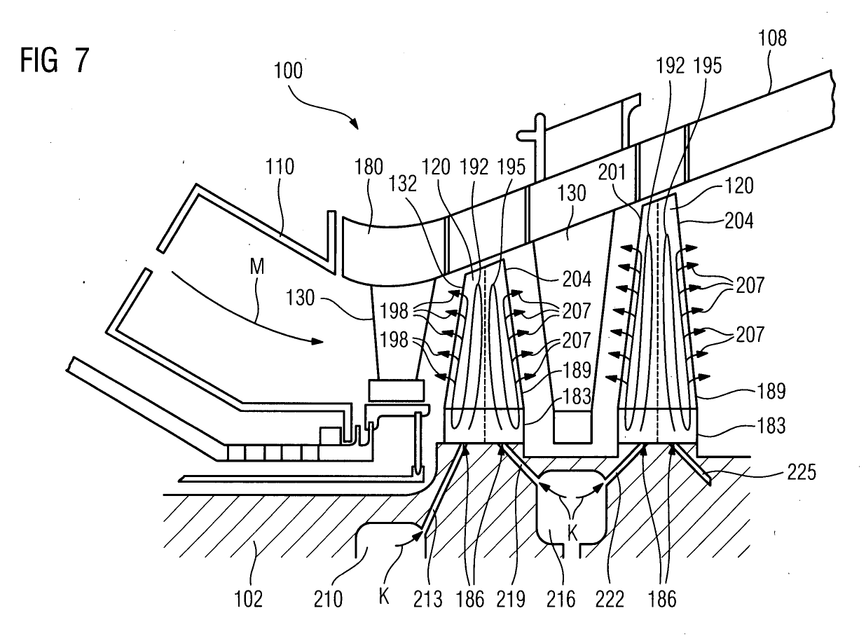

FIG. 7 schematically shows how turbine blades are cooled. To achieve a comparatively high efficiency, the gas turbine 100 is designed for a comparatively high outlet temperature of the working medium M leaving the combustion chamber 110, of approximately 1200° C. to 1300° C. To make this possible, at least some of the moving blades 120 and the stationary blades 130 are designed such that they can be cooled by cooling air K as the cooling medium. In Figure ? it can be seen that the working medium M flowing out from the combustion chamber 110 initially meets a number of stationary blades 130, which form what is known as the first row of stationary blades 115 and are suspended in the combustion chamber 110 by means of their respective platform 180. As seen in the direction of flow of the working medium M, this is followed by the moving blades 120, forming the first row of moving blades, the stationary blades 130, forming the second row of stationary blades, and the moving blades 120, forming the second row of moving blades.

The moving blades 120 are designed for particularly reliable feeding with cooling air K substantially over the entire base cross section of their respective blade root 183. For this purpose, the blade root 183 of the respective moving blade 120 is in each case provided with a plurality of inflow openings 186 for cooling air K. The inflow openings 186 of each moving blade 120 are in this case arranged one behind the other, as seen for example in the longitudinal direction of the turbine shaft 102. Each inflow opening 186 is respectively assigned a part-duct 192 and 195 for cooling air K, made to extend through the blade airfoil 189 of the respective moving blade 120.

These part-ducts 192, 195 may be coated by the method according to the invention.

The part-duct 192 of the respective moving blade 120 that is assigned to the front inflow opening 186, as seen in the direction of flow of the working medium M, is in this case made to extend in a meandering manner from the assigned inflow opening 186 through the front part of the respective moving blade 120, as represented merely schematically in the figure.

The part-duct 192 in this case opens out on the outlet side into a number of outlet openings 198 for the cooling air K, which are assigned at the front edge 201 of the respective moving blade 120, as seen in the direction of flow of the working medium M. By contrast with this, the rear inflow opening 186 in each case of the respective moving blade 120, as seen in the direction of flow of the working medium M, communicates with a part-duct 195 likewise made to extend in a meandering manner in the rear part of the respective moving blade 120. The part-duct 195 opens out on the outlet side into a number of outlet openings 207 arranged at the rear edge 204 of the respective moving blade 120.

On the cooling air side, the part-ducts 192, 195 of each moving blade 120 are for example completely isolated from one another. This makes it possible for each part-duct 192, 195 to be fed with cooling air K adapted to the respective requirements with regard to its operating parameters. In this case, allowance can be made in particular for the fact that the pressure level which the cooling air K must have or exceed in the region of the outlet openings 198 or 207 is dependent on the position of the respective moving blade 120 along the turbine shaft 102 and on whether the exiting of the cooling air K takes place counter to the direction of flow of the working medium M or in the direction of flow of the working medium M. Therefore, the cooling air K fed to the outlet openings 198 must in particular have a higher operating pressure than the cooling air K fed to the outlet openings 207.

In order for example to permit separate feeding of cooling air K to the part-ducts 192, 195 to maintain these different boundary conditions, the cooling air supply system of the gas turbine 100 must be correspondingly adapted. In particular, the cooling air supply system comprises a first plenum chamber 210, integrated in the turbine shaft 102, which in the exemplary embodiment according to the figure is connected via a bore 213, which is made to extend in the turbine shaft 102, to the first inflow opening 186, as seen in the longitudinal direction of the turbine shaft 102, of each of the moving blades 120 forming the first row of moving blades.

Furthermore, the cooling air supply system comprises, for example, a second plenum chamber 216 for cooling air K. As seen in the longitudinal direction of the turbine shaft 102, this second plenum chamber is arranged behind the first plenum chamber 210 and is likewise integrated in the turbine shaft 102. The second plenum chamber 216 is connected on the cooling air side via a bore 219 to the rear inlet opening 186, seen in the longitudinal direction of the turbine shaft 102, of each of the moving blades 120 forming the first row of moving blades. Furthermore, the second plenum chamber 216 is connected via a bore 222 to the front inflow opening 186, seen in the longitudinal direction of the turbine shaft 102, of each of the moving blades 120 forming the second row of moving blades.

Further plenum chambers may also be provided for the rows of moving blades which follow, which is indicated by the bore 225 assigned to the rear inflow opening 186, seen in the longitudinal direction of the turbine shaft 102, of the moving blades 120 forming the second row of moving blades.

With respect to each individual moving blade 120, it is ensured by this cooling air conduction that each inflow opening 186 of each moving blade 120 is respectively assigned a separate cooling air supply that is integrated in the turbine shaft. Each inflow opening 186, and with it also the respectively downstream part-duct 192, 95, can consequently be subjected to cooling air K independently of the other part-duct 195 or 192, respectively. The part-flows of cooling air K that are formed in this way can therefore be adapted to the individual conditions prevailing on the outlet side. In particular, the part-duct 192 can be subjected to cooling air K that is under higher pressure in comparison with the part-duct 195. For this purpose, the first plenum chamber 210 is fed with correspondingly high-grade cooling air K, under a comparatively high pressure. On the other hand, the second plenum chamber 216, from which the second part-duct 192 of the moving blades 120 forming the first row of moving blades is supplied with cooling air K, is fed with comparatively lower-grade cooling air K, under a lower pressure. The total quantity of high-grade cooling air K at a particularly high pressure can consequently be kept comparatively low and restricted exclusively to those regions of the respective moving blade 120 for which it is actually necessary for them to be supplied with such high-grade cooling air K.

According to FIG. 7, the inflow openings 186 of the moving blades 120 are arranged in the bottom region of the respective blade root 183.

FIG. 8 shows by way of example a gas turbine 100 in a longitudinal partial section.

The gas turbine 100 has in the interior a rotor 103, which is rotatably mounted about an axis of rotation 102 and is also referred to as a turbine runner.

Following one another along the rotor 103 are an intake housing 104, a compressor 105, a combustion chamber 110, for example of a toroidal form, in particular an annular combustion chamber 106, with a number of coaxially arranged burners 107, a turbine 108 and the exhaust housing 109.

The annular combustion chamber 106 communicates with a hot gas duct 111, for example of an annular form. There, the turbine 108 is formed for example by four successive turbine stages 112.

Each turbine stage 112 is formed for example by two blade rings. As seen in the direction of flow of a working medium 113, a row of stationary blades 115 is followed in the hot gas duct 111 by a row 125 formed by moving blades 120.

The stationary blades 130 are in this case fastened to an inner housing 138 of a stator 143, whereas the moving blades 120 of a row 125 are attached to the rotor 103, for example by means of a turbine disk 133.

Coupled to the rotor 103 is a generator or a machine (not represented).

During the operation of the gas turbine 100, air 135 is sucked in by the compressor 105 through the intake housing 104 and compressed. The compressed air provided at the end of the compressor 105 on the turbine side is passed to the burners 107 and mixed there with a fuel. The mixture is then burned in the combustion chamber 110 to form the working medium 113. From there, the working medium 113 flows along the hot gas duct 111, past the stationary blades 130 and the moving blades 120. At the moving blades 120, the working medium 113 expands, transferring momentum, so that the moving blades 120 drive the rotor 103 and the latter drives the machine coupled to it.

The components that are exposed to the hot working medium 113 are subjected to thermal loads during the operation of the gas turbine 100. The stationary blades 130 and moving blades 120 of the first turbine stage 112, as seen in the direction of flow of the working medium 113, are thermally loaded the most, along with the heat shielding bricks lining the annular combustion chamber 106.

In order to withstand the temperatures prevailing there, these may be cooled by means of a coolant.

Similarly, substrates of the components may have a directed structure, i.e. they are monocrystalline (SX structure), or have only longitudinally directed grains (DS structure).

Iron-, nickel-or cobalt-based superalloys are used for example as the material for the components, in particular for the turbine blade 120, 130 and components of the combustion chamber 110.

Such superalloys are known for example from EP 1 204 776, EP 1 306 454, EP 1 319 729, WO 99/67435 or WO 00/44949; these documents constitute part of the disclosure.

Similarly, the blades 120, 130 may have coatings against corrosion (MCrAlX; M is at least one element of the group comprising iron (Fe), cobalt (Co) and nickel (Ni), X is an active element and represents yttrium (Y) and/or silicon and/or at least one element of the rare earths) and against heat by a heat insulating layer.

The heat insulating layer consists for example of ZrO₂, Y₂O₄—ZrO₂, i.e. it is not stabilized or is partly or completely stabilized by yttrium oxide and/or calcium oxide and/or magnesium oxide.

Columnar grains are produced in the heat insulating layer by suitable coating methods, such as for example electron-beam physical vapor deposition (EB-PVD).

The stationary blade 130 has a stationary blade root facing the inner housing 138 of the turbine 108 (not represented here) and a stationary blade head, lying opposite the stationary blade foot. The stationary blade head is facing the rotor 103 and fixed to a fastening ring 140 of the stator 143.

1-14. (canceled)

15. A method for coating an inner surface of a component with a cavity, comprising:
introducing a mixture of coating material having a specific evaporating temperature, and a carrier material, which is thermally stable at room temperature and thermally unstable at the evaporating temperature of the coating material and which contains the coating material into the cavity; and
supplying energy so that the carrier material decomposes and the coating material is deposited via a gas phase on the inner surfaces, wherein
a polymer is used as the carrier material.

16. The method as claimed in claim 15, wherein the polymer is polyurethane.

17. The method as claimed in claim 15, wherein the coating material is present in the carrier material in the form of nanoparticles.

18. The method as claimed in claim 15, wherein the coating material is metallic.

19. The method as claimed in claim 15, wherein the coating material is ceramic.

20. The method as claimed in claim 15, wherein a through-opening is coated.

21. The method as claimed in claim 20, wherein the through-opening is a cooling duct.

22. The method as claimed in claim 15, wherein an inner alitizing is performed.

23. The method as claimed in claim 15, wherein the coating material comprises a number of elements.

24. The method as claimed in claim 15, wherein the carrier material contains a coarse material comprising particles of grater than one micrometer in size.

25. The method as claimed in claim 24, wherein the coarse material is more thermally stable than the coating material.

26. The method as claimed in claim 24, wherein the coarse material a is ceramic.

27. The method as claimed in claim 24, wherein the ceramic is aluminum oxide.

28. The method as claimed in claim 15, wherein a meandering cooling configuration of a gas turbine component is coated.

29. The method as claimed in claim 28, wherein the coarse particles are deposited in such a way that they protrude from a surface of a coating.

30. A gas turbine component, comprising:
a body having a cavity;
a mixture comprising a coating material and a polymer carrier material arranged within the cavity, the mixture being thermally stable at room temperature and thermally unstable at an evaporating temperature of the coating material; and
a coating formed on an inner surface of the cavity by supplying energy to the mixture such that the carrier material decomposes and the coating material is deposited via a gas phase on the inner surfaces of the cavity.

31. The component as claimed in claim 30, wherein coarse particles protrude from a surface of the coating.
